(19) United States
(12) Patent Application Publication
(10) Pub. No.: US 2007/0004193 A1
(43) Pub. Date: Jan. 4, 2007

(54) Method for reworking low-k dual damascene photo resist

(75) Inventors: Tsang-Jiuh Wu, HsinChu (TW); Chen-Nan Yeh, Hsi-Chih (TW); Dean Li, (US); Hui Ouyang, Hsinchu (TW)

Correspondence Address: DUANE MORRIS, LLP;IP DEPARTMENT, 30 SOUTH 17TH STREET, PHILADELPHIA, PA, 19103-4196, US

(73) Assignee: Taiwan Semiconductor Manufacturing Co., Ltd.

(21) Appl. No.: 11/173,275

(22) Filed: Jul. 1, 2005

(51) Int. Cl. H01L 21/4763

(52) U.S. Cl. 438/624; 438/637; 438/763

(57) ABSTRACT

A new method of forming a dual damascene structure involves forming a via-level precursor structure on a substrate and spin coating an oxide protective layer over the bottom anti-reflective coating, which is the last layer of the via-level precursor structure. A trench-level photoresist layer is deposited over the oxide protective layer to form a trench pattern etch mask. The oxide protective layer protects the BARC layer and the via plugs from photoresist removing process. When and if the trench-level photoresist layer is to be reworked, the trench-level photoresist layer is simply removed without removing the BARC layer and the via plugs under the oxide protective layer.

### BACKGROUND

The present invention relates generally to photolithography processing in semiconductor device fabrication, and more particularly, to photo resist rework process in the dual damascene process for fabricating semiconductor devices.

Referring to FIGS. 1A and 1B, a conventional dual damascene process will be described. A substrate 10 is a semiconductor material, single crystal Si, Ge, or GaAs with integrated circuits thereon. An etch stop layer 11 is formed over the substrate 10. Next, an interlevel dielectric layer (“ILD”) 12, usually a low-k dielectric constant insulator, is formed over the etch stop layer 11. An inorganic anti-reflective coating (“ARC”) 13 is then formed over the ILD layer 12. The ARC layer 13, which is the first ARC layer, is generally an inorganic material such as silicon nitride, silicon oxynitride, and silicon carbide, with an approximate thickness range from 300 to 1000 Angstroms.

Next, via holes 15 are formed by first applying a photoresist coating 14 over the inorganic ARC layer 13 and exposing and developing the via hole pattern in the photoresist coating 14. The underlying ARC layer 13 and the ILD layer 12 are etched using the patterned photoresist coating 14 as the mask to form the via holes 15. After the via holes 15 are formed, the photoresist coating 14 is stripped.

Referring to FIG. 1C, next, the via holes 15 are filled with spin-on glass (SOG) via plug material 16 to form via plugs. The SOG via plug material 16 are generally an organic polymer with cross-linking compounds. Some examples of commercially available pure resin material are Shipley ViPR material and TOK HEGF material. The via plug material 16 generally has a higher etch rate than the ILD layer 12, approximately 1.3 to 1.6 times the etch rate of the ILD layer 12.

A bottom anti-reflective coating layer (BARC) 17 is then applied over the entire surface covering the ARC layer 13 and the via plugs 16. The via plug material 16 may be pure resin or the same material as the BARC layer 17, which may be silicon nitride, silicon carbide, and silicon oxynitride. If the via plugs 16 and the BARC layer 17 are the same materials, they may be formed at the same time by one spin coating process rather than in two separate steps. The BARC layer 17 forms an anti reflective layer during the subsequent trench forming steps. The structure up to and including the BARC layer 17 will be referred to herein as a via-level precursor structure.

Next, with reference to FIG. 1D, in a conventional dual damascene process, a layer of trench-level photoresist 18 is applied on the BARC layer 17 in order to lithographically form trench patterns. The trench-level photoresist layer 18 is exposed and developed with a pattern 19 for forming trenches. Sometimes, the patterned photoresist layer 18 may be defective and needs to be reworked. In the conventional dual damascene process, this reworking of the trench-level photoresist layer 18 involves stripping off the trench-level photoresist 18. But the photoresist strip process also removes the BARC layer 17 and the via plug 16. As shown in FIG. 1E, this rework process often results in damaged low-k ILD 12a along the sidewalls of the via openings 15. The damaged low-k dielectric material often may interact with the via plug material and form a hard skin, which has lower etch rate than undamaged low-k dielectric material. The hard skin formed by the damaged low-k dielectric in the via sidewalls result in via defects called “fencing.” And, because the BARC layer 17 and the via plug 16 has to be reapplied, additional processing time and material are incurred in the trench-level photoresist rework associated with the conventional dual damascene process is also costly.

Accordingly, there is a need for an improved dual damascene process that eliminates the above described concerns related to the trench-level photoresist rework process.

### SUMMARY

According to an embodiment of the invention, a new method of forming a dual damascene structure is disclosed. The method includes forming a via-level precursor structure on a substrate. The via-level precursor structure comprises via openings formed in a low-k interlevel dielectric (“ILD”) layer that is coated with an anti-reflective coating layer. The via openings are filled with a via plug material forming via plugs and a bottom anti-reflective coating layer over the ILD layer and the via plugs. An oxide protective layer is then spin coated over the bottom anti-reflective coating. Next, a trench-level photoresist layer is deposited over the oxide protective layer to form a trench pattern etch mask. At this point, if the trench-level photoresist layer needs to be reworked, the photoresist layer is simply removed. Unlike in the conventional dual damascene process, the oxide protective layer provides protection from the photoresist etchant and the BARC layer and the via plugs remain intact, thus, allowing rework of the trench-level photoresist layer without removing or damaging the structures under the BARC layer. After the first trench-level photoresist layer is removed, a new trench-level photoresist layer is deposited over the oxide protective layer and exposed and developed to form trench patterns.

The new process described herein allows the trench-level photoresist to be reworked more reliably and also more cost effectively. Because the BARC layer and the via plugs are not removed during the trench-level photoresist rework, the processing time lost in reapplying the via plugs and the BARC layer and the extra costs associated with the additional via plug and BARC material are saved. Also, because the via plugs remain intact, according to the new process, the low-k ILD layer along the sidewalls of the via openings are not damaged during the trench-level photoresist removal process.

### BRIEF DESCRIPTION OF THE DRAWINGS

FIGS. 1A-E, in cross-sectional representations illustrate a portion of a conventional method of forming dual damascene structure including trench-level photoresist rework.

FIGS. 2A-E, in cross-sectional representations illustrate an embodiment of the new method of forming dual damascene structure including trench-level photoresist rework which eliminates the problems related to the conventional process.

FIG. 3 is a flow chart of an exemplary process.

### DETAILED DESCRIPTION

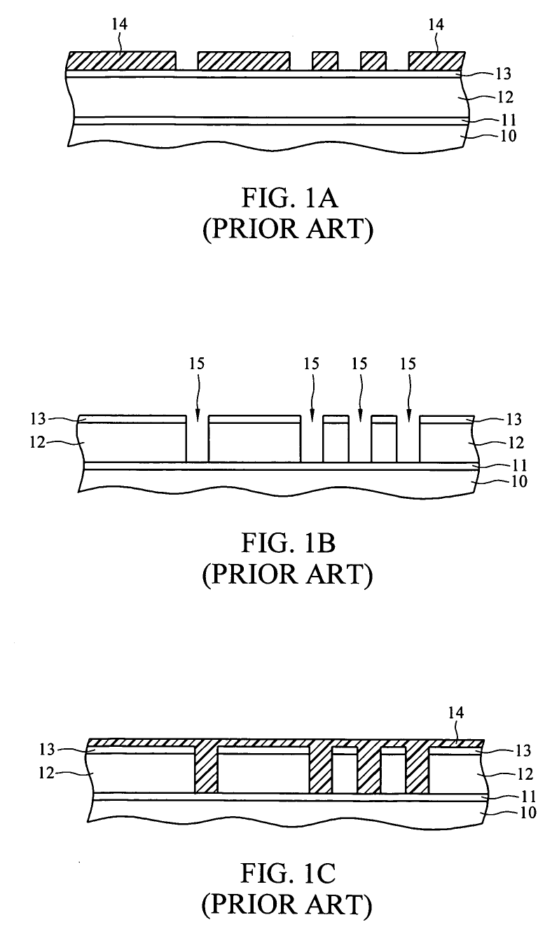

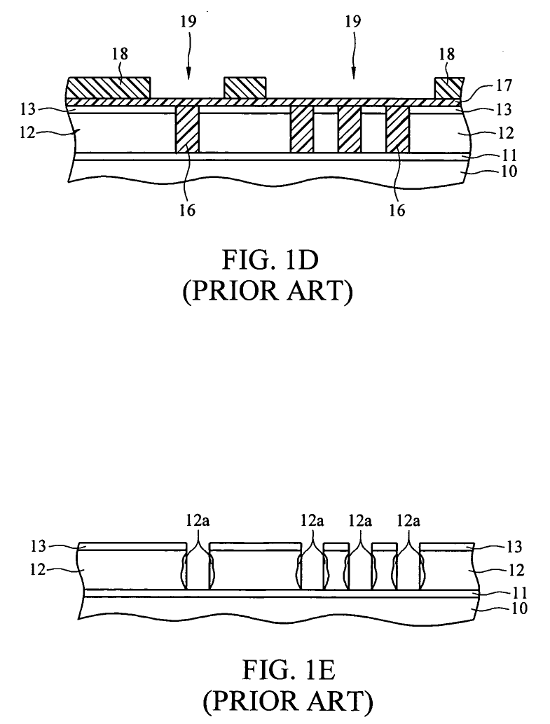

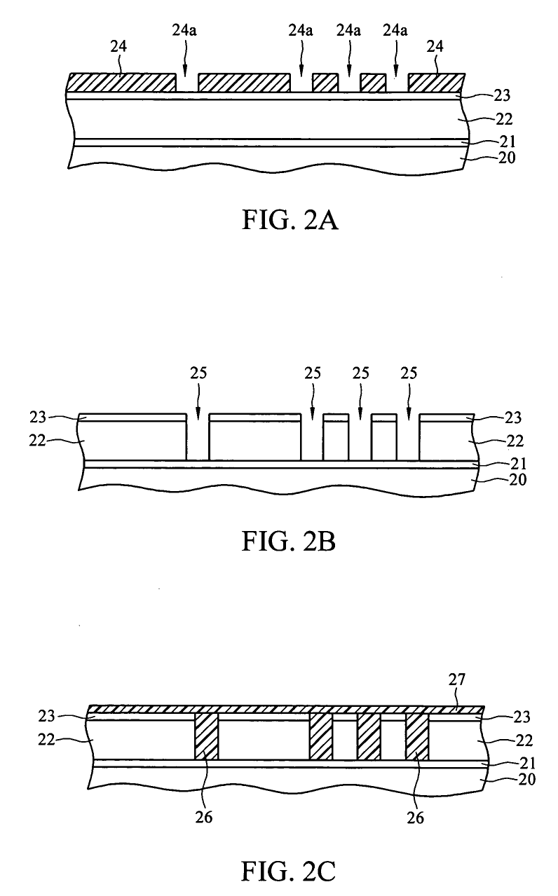

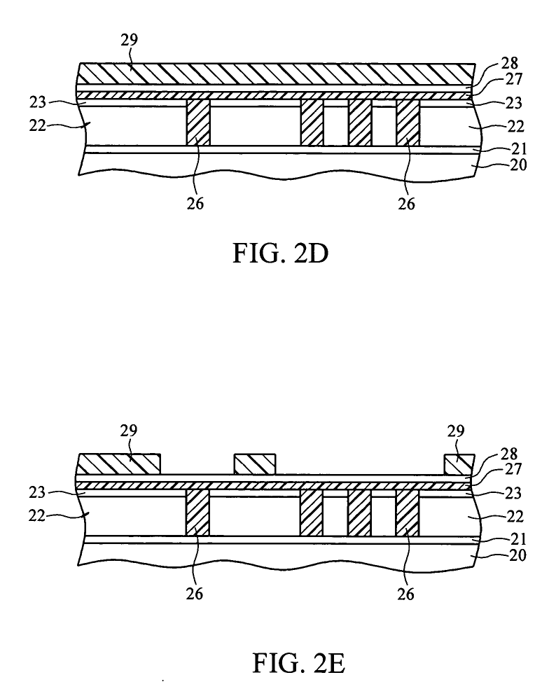

Referring to FIGS. 2A-G, a dual damascene structure and a process of making the dual damascene structure according to an embodiment of the invention will be described. The process of forming a via-level precursor structure up to the spin coating of the BARC layer 27 is as in the conventional process illustrated in FIGS. 1A-1C. With reference to FIG. 2A, the substrate 20 is a semiconductor material, single crystal Si, Ge, or GaAs, with integrated circuits thereon. An etch stop layer 21 is formed over the substrate 20. Next, an interlevel dielectric layer 22 (ILD), usually a low k insulator, is formed over the etch stop layer 21. The etch stop layer 21, which is over the substrate, is selected from the group consisting of silicon nitride, silicon oxynitride, and silicon carbide, with an approximate thickness range from 300 to 1,000 Angstroms. An inorganic anti-reflective coating 23 (ARC) is formed over the ILD layer 22. The ARC 23 over the ILD layer 22 is usually an inorganic material selected from the group consisting of silicon nitride, silicon oxynitride, and silicon carbide, with an approximate thickness range from 300 to 1,000 Angstroms. Next, a via-patterning photoresist coating 24 is formed over the inorganic anti-reflective coating 23. This photoresist coating 24 is exposed, developed and patterned into a mask for etching via openings in the ILD layer 22. In FIG. 2A, the photoresist coating 24 is shown with patterned holes 24a.

Referring to FIG. 2B, next, the ARC layer 23 and the ILD 22 are etched using the photoresist coating 24 as the mask to form via openings 25. The via openings 25 are etched down to the etch stop layer 21. The photoresist coating 24 is then stripped away leaving behind the structure shown in FIG. 2B.

Next, referring to FIG. 2C, SOG via plugs 26 and BARC layer 27 are applied. The SOG via plugs 26 and the BARC layer 27 may be formed of same material or different material. If same material is used for both the SOG via plugs 26 and the BARC layer 27, the layers may be formed in one spin coating step. Alternatively, the via plugs 26 and the BARC layer 27 may be applied in two separate spin coating steps, first spin coating the via plugs 26 and then spin coating the BARC layer 27. The BARC material may be organic polymer mixtures with thermally cross-linking polymer resins mixed with dyes. Both the polymer resins and/or the dyes are intrinsically light absorbing polymers. The thickness of the BARC layer 27 is controlled to approximately 1,000 Angstroms or less. The thickness of the BARC layer 27 can be controlled in a number of ways in these various spin coating process options. These different variations of depositing the via plugs 26 and the BARC layer 27 are disclosed in U.S. Published Patent Application No. 2005/0014362 A1, the disclosure of which is incorporated herein by reference.

As shown in FIG. 2D, according to an embodiment, a SOG oxide protective layer 28 is applied over the BARC layer 27 before a coating of the trench-level photoresist 29 is applied. The SOG oxide protective layer 28 acts as an etch stop layer to protect the underlying organic resist BARC layer 27 when the trench-level photoresist 29 has to be reworked. For example, referring to FIG. 2E, the trench-level photoresist 29 has been exposed and developed with trench patterns 30. Now, if the trench-level photoresist 29 needs to be reworked, the photoresist layer 29 is removed by any one of the commonly used photoresist removal process. But, unlike in the conventional photoresist rework process described earlier, the SOG oxide protective layer 28 protects the BARC layer 27 and the via plugs 26 from the photoresist etching process. A new trench-level photoresist 29 can be applied over the BARC layer 27 and start the trench patterning process again. Because the BARC layer 27 and the via plugs 26 do not have to be laid down again, the resulting trench-level photoresist rework process is less costly both in material costs as well as the process cycle time.

The anti-reflective coating 23 and the etch stop layer 21 both form etch stop layers. Both the anti-reflective coating 23 and the etch stop layer 21 are selected from the group consisting of silicon nitride, silicon carbide, and silicon oxynitride. The anti-reflective coating 23, over the ILD layer 22, has an approximate thickness between 300 to 1,000 Angstroms.

Referring to FIG. 2F, next in the process the exposed layer of the low k, interlevel dielectric 22 material and exposed anti-reflective coating 23 are etched to form trench openings 290 (arrows). Some of the via plug material 27 remains partially in the via openings, for both densely and sparely populated via regions.

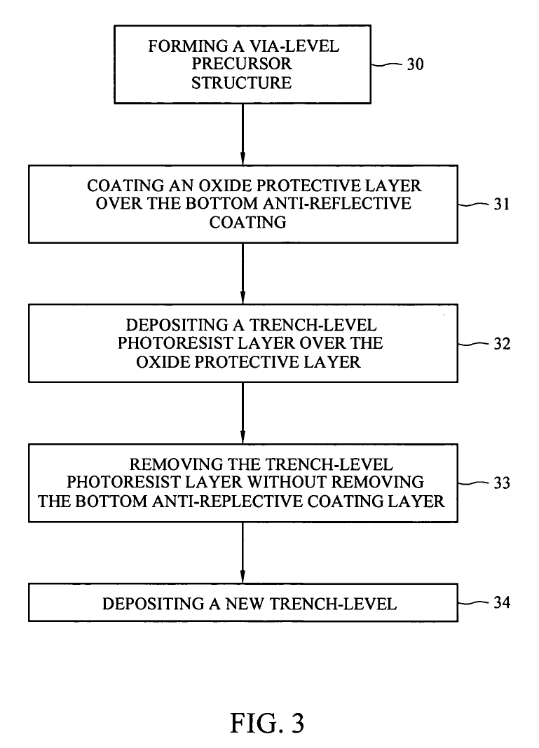

FIG. 3 is a flow chart diagram of the exemplary process.

At step 30, a via-level precursor structure is formed.

At step 31, an oxide protective layer is coated over the bottom anti-reflective coating.

At step 32, a trench-level photoresist layer is deposited over the oxide protective layer.

At step 33, the trench-level photoresist layer is removed without removing the bottom anti-reflective coating in order to rework the trench-level photoresist layer.

At step 34, a new trench-level photoresist layer is deposited over the oxide protective layer to form trench patterns in the new trench-level photoresist layer.

While the invention has been particularly shown and described with reference to the preferred embodiments thereof, it will be understood by those skilled in the art that various changes in form and details may be made without departing from the spirit and scope of the invention. Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A method of reworking a trench-level photoresist layer in a low-k dual damascene structure, the method comprising:
forming a via-level precursor structure comprising via openings formed in a low-k dielectric layer, the low-k dielectric layer covered with an anti-reflective coating layer, the via openings having via plugs therein, and further forming a bottom anti-reflective coating layer over the low-k dielectric layer and the via plugs;
coating an oxide protective layer over the bottom anti-reflective coating layer;
depositing a first trench-level photoresist layer over the oxide protective layer;
removing the first trench-level photoresist layer without removing the bottom anti-reflective coating in order to rework the trench-level photoresist layer; and
depositing a second trench-level photoresist layer over the oxide protective layer to form trench patterns in the new trench-level photoresist layer.

2. The method of claim 1, wherein the oxide protective layer over the bottom anti-reflective coating layer is a spin-on-glass type.

3. The method of claim 1, wherein the step of coating the oxide protective layer over the bottom anti-reflective coating involves spin coating.

4. The method of claim 1, wherein the bottom anti-reflective coating layer comprises a light absorbing thermally cross-linking polymer resin.

5. The method of claim 3, wherein the bottom anti-reflective coating layer further comprises a light absorbing dye.

6. The method of claim 1, wherein the via plug material and the bottom anti-reflective coating layer are made of same material.

7. The method of claim 6, wherein the via plug material and the bottom anti-reflective coating layer comprise a light absorbing thermally cross-linking polymer resin.

8. The method of claim 7, wherein the via plug material and the bottom anti-reflective coating layer further comprise a light absorbing dye.

9. The method of claim 1, wherein the anti-reflective coating layer over the low-k dielectric layer has an approximate thickness between 300 to 1000 Angstroms.

10. The method of claim 1, wherein the anti-reflective coating layer over the low-k dielectric layer is selected from the group consisting of silicon nitride, silicon carbide, and silicon oxynitride.

11. A method of reworking a trench-level photoresist layer in a low-k dual damascene structure, the method comprising:
forming a via-level precursor structure comprising via openings formed in a low-k interlevel dielectric layer, the low-k interlevel dielectric layer covered with an anti-reflective coating layer, the via openings having via plugs therein, and further forming a bottom anti-reflective coating layer over the low-k interlevel dielectric layer and the via plugs;
coating an oxide protective layer over the bottom anti-reflective coating layer;
depositing a first trench-level photoresist layer over the oxide protective layer;
removing the first trench-level photoresist layer without removing the bottom anti-reflective coating in order to rework the trench-level photoresist layer; and
depositing a second trench-level photoresist layer over the oxide protective layer to form trench patterns in the new trench-level photoresist layer.

12. The method of claim 11, wherein the oxide protective layer over the bottom anti-reflective coating layer is a spin-on-glass type.

13. The method of claim 11, wherein the step of coating the oxide protective layer over the bottom anti-reflective coating involves spin coating.

14. The method of claim 11, wherein the bottom anti-reflective coating layer comprises a light absorbing thermally cross-linking polymer resin.

15. The method of claim 13, wherein the bottom anti-reflective coating layer further comprises a light absorbing dye.

16. The method of claim 11, wherein the via plug material and the bottom anti-reflective coating layer are made of same material.

17. The method of claim 16, wherein the via plug material and the bottom anti-reflective coating layer comprise a light absorbing thermally cross-linking polymer resin.

18. The method of claim 17, wherein the via plug material and the bottom anti-reflective coating layer further comprise a light absorbing dye.

19. The method of claim 11, wherein the anti-reflective coating layer over the low-k dielectric layer has an approximate thickness between 300 to 1000 Angstroms.

20. The method of claim 11, wherein the anti-reflective coating layer over the low-k dielectric layer is selected from the group consisting of silicon nitride, silicon carbide, and silicon oxynitride.
